(19) United States
(12) Patent Application Publication
(10) Pub. No.: US 2025/0251666 A1
(43) Pub. Date: Aug. 7, 2025

(54) RESIST UNDERLAYER FILM-FORMING COMPOSITION, AND METHOD FOR MANUFACTURING SEMICONDUCTOR SUBSTRATE

(71) Applicant: JSR CORPORATION, Tokyo (JP)

(72) Inventors: Shuhei YAMADA, Tokyo (JP); Satoshi DEI, Tokyo (JP); Yuya HAYASHI, Tokyo (JP); Shunpei AKITA, Tokyo (JP); Eiji YONEDA, Tokyo (JP)

(73) Assignee: JSR CORPORATION, Tokyo (JP)

(21) Appl. No.: 19/093,450

(22) Filed: Mar. 28, 2025

Related U.S. Application Data
(63) Continuation-in-part of application No. PCT/JP2023/033814, filed on Sep. 19, 2023.

(30) Foreign Application Priority Data
Sep. 30, 2022 (JP) 2022-157452

(51) Int. Cl. G03F 7/11; G03F 7/004; G03F 7/20; H01L 21/027; H01L 21/308

(52) U.S. Cl. CPC G03F 7/11; G03F 7/0043; G03F 7/2004; H01L 21/0275; H01L 21/3081; H01L 21/3086

(57) ABSTRACT

A composition includes a compound including an iodine atom, and a solvent. The compound including an iodine atom is a polymer including a repeating unit represented by formula (1), an aromatic ring-containing compound including an iodine atom and having a molecular weight of 750 or more and 3,000 or less, or a combination thereof. A content ratio of the compound including an iodine atom to components other than the solvent in the composition for forming an underlayer film is 50% by mass or more. In the formula (1), Ar¹ is a divalent group including an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ includes an iodine atom.

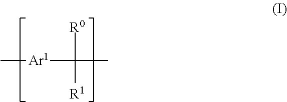

### CROSS-REFERENCE TO RELATED APPLICATIONS

The present application is a continuation-in-part application of International Patent Application No. PCT/JP2023/033814 filed Sep. 19, 2023, which claims priority to Japanese Patent Application No. 2022-157452 filed Sep. 30, 2022. The contents of these applications are incorporated herein by reference in their entirety.

### BACKGROUND OF THE DISCLOSURE

### Technical Field

The present disclosure relates to a composition for forming a resist underlayer film and a method for manufacturing a semiconductor substrate.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for resist underlayer film formation in such EUV exposure (see WO 2021/157551A).

### SUMMARY

According to an aspect of the present disclosure, a composition includes a compound including an iodine atom (hereinafter, also referred to as “compound [A]”), and a solvent (hereinafter, also referred to as “solvent [B]”). The compound including an iodine atom is a polymer including a repeating unit represented by formula (1) (hereinafter, also referred to as “polymer [A1]”), an aromatic ring-containing compound including an iodine atom and having a molecular weight of 750 or more and 3,000 or less (hereinafter, also referred to as “aromatic ring-containing compound [A2]”), or a combination thereof. A content ratio of the compound including an iodine atom to components other than the solvent in the composition for forming an underlayer film is 50% by mass or more. In the formula (1), Ar¹ is a divalent group including an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ includes an iodine atom.

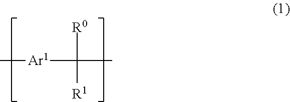

According to another aspect of the present disclosure, a method for manufacturing a semiconductor substrate, includes: applying a composition for forming a resist underlayer film directly or indirectly to a substrate to form a resist underlayer film; applying a composition for forming a resist film to the resist underlayer film to form a resist film; exposing the resist film to extreme ultraviolet rays; and developing at least the exposed resist film. The composition for forming a resist underlayer film includes a compound including an iodine atom, and a solvent. The compound including an iodine atom is a polymer including a repeating unit represented by formula (1), an aromatic ring-containing compound including an iodine atom and having a molecular weight of 750 or more and 3,000 or less, or a combination thereof. A content ratio of the compound including an iodine atom in components other than the solvent in the composition for forming an underlayer film is 50% by mass or more.

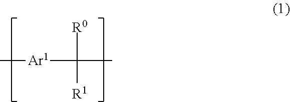

In the formula (1), Ar¹ is a divalent group including an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ includes an iodine atom.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

While the line width of a resist pattern formed through exposure to extreme ultraviolet rays and development is being miniaturized, there is a request for resist pattern rectangularity of securing rectangularity of a resist pattern by suppressing trailing of the pattern at the bottom of a resist film.

According to the composition for forming a resist underlayer film, it is possible to form a resist underlayer film excellent in resist pattern rectangularity, even when exposed to extreme ultraviolet rays. According to the method for manufacturing a semiconductor substrate, it is possible to efficiently manufacture a semiconductor substrate since a composition for forming a resist underlayer film capable of forming a resist underlayer film excellent in resist pattern rectangularity is used. Therefore, they can suitably be used for, for example, producing semiconductor devices expected to be further microfabricated in the future.

Hereinafter, a composition for forming a resist underlayer film and a method for manufacturing a semiconductor substrate according to each embodiment of the present disclosure will be described in detail. Combinations of suitable modes in embodiments are also preferred.

### <<Composition for Forming a Resist Underlayer Film>>

The composition for forming a resist underlayer film (hereinafter, also simply referred to as the “composition”) is used as a composition for forming an underlayer film of a resist film to be exposed to extreme ultraviolet rays, and contains a compound [A] and a solvent [B]. The composition may include an optional component as long as the effect of the composition is not impaired.

Each component contained in the composition will be described below.

### <Compound [A]>

The compound [A] is a compound having an iodine atom, and is a polymer [A1], an aromatic ring-containing compound [A2](however, excluding compounds corresponding to the polymer [A1]), or a combination thereof. Each of the polymer [A1] and the aromatic ring-containing compound [A2] may be used singly or in combination of two or more kinds thereof.

### (Polymer [A1])

The polymer [A1] as the compound [A] is a polymer having a repeating unit represented by formula (1). The polymer [A1] may have two or more kinds of repeating units represented by formula (1).

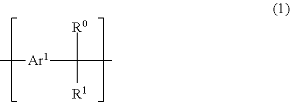

in the formula (1), Ar¹ is a divalent group having an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ has an iodine atom.

In the polymer [A1], at least one of Ar¹, R⁰ or R¹ has an iodine atom. It is preferred that at least one of Ar¹ or R¹ has an iodine atom, and it is more preferred that R¹ has an iodine atom. In any of the main chain moiety or the side chain moiety, an effect of improving the secondary electron generation efficiency (and hence the sensitivity) due to iodine atoms, which have a high absorption efficiency for extreme ultraviolet rays, is attained, but the sensitivity can be further enhanced by introducing an iodine atom into the side chain moiety, which has a high degree of freedom.

In the formula (1), examples of the aromatic ring having 5 to 40 ring atoms in Ar¹ include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine group, or combinations thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring and a perylene ring.

In the present specification, the term “ring members” refers to the number of atoms constituting the ring. For example, a biphenyl ring has 12 ring members, a naphthalene ring has 10 ring members, and a fluorene ring has 13 ring members. The term “polycyclic condensed aromatic ring” refers to a polycyclic aromatic hydrocarbon ring composed of a plurality of aromatic rings sharing a side (a bond between two adjacent carbon atoms).

In the formula (1), suitable examples of the divalent group having an aromatic ring having 5 to 40 ring members represented by Ar¹ include a group obtained by removing two hydrogen atoms from the aromatic ring having 5 to 40 ring members in Ar¹ or a combination of the aromatic ring and a chain structure. In a case where aromatic rings are combined, the aromatic rings may be bonded to each other via a single bond in addition to a condensed ring structure.

As the chain structure, a chain hydrocarbon having 1 to 20 carbon atoms can be suitably adopted. Examples of the chain hydrocarbon having 1 to 20 carbon atoms include methane, ethane, propane, butane, hexane, and octane. These may be either linear or branched. Among these, a linear or branched alkane having 1 to 8 carbon atoms is preferred.

In the formula (1), examples of the monovalent organic group having 1 to 40 carbon atoms represented by R⁰ and R¹ include a monovalent hydrocarbon group having 1 to 20 carbon atoms, a group containing a divalent heteroatom-containing group between two carbon atoms of this hydrocarbon group or at the end of the hydrocarbon group, a group obtained by substituting some or all of the hydrogen atoms of the hydrocarbon group with a monovalent heteroatom-containing group, and a combination thereof.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and a combination thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopropyl group, a cyclobutyl group, a cyclopentyl group, and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, —SO—, —SO₂—, or groups obtained by combining them.

Examples of the monovalent heteroatom-containing group include a hydroxy group, a sulfanyl group, a cyano group, a nitro group, and halogen atoms.

R⁰ is preferably a hydrogen atom.

R¹ preferably has an aromatic ring having 5 to 40 ring members. As the aromatic ring having 5 to 40 ring members in R¹, an aromatic ring having 5 to 40 ring members in Ar¹ can be suitably adopted. In this case, it is preferred that at least one hydrogen atom of the aromatic ring is substituted with an iodine atom. The number of iodine atoms on the aromatic ring is preferably an integer from 1 to 4, more preferably an integer from 1 to 3, still more preferably 1 or 2 from the viewpoint of the solubility of the composition.

The polymer [A1] preferably has at least one group selected from the group consisting of a hydroxy group, a group represented by formula (2-1), and a group represented by formula (2-2) (hereinafter, the group represented by formula (2-1) or the group represented by formula (2-2) will also be referred to as “group (a)”).

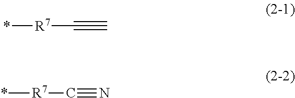

in the formulas (2-1) and (2-2), R⁷ is each independently a divalent organic group having 1 to 20 carbon atoms or a single bond; and * is a bond with a carbon atom in the aromatic ring.

In the formulas (2-1) and (2-2), as the divalent organic group having 1 to 20 carbon atoms represented by R⁷, a group in which one hydrogen atom is removed from the structure corresponding to 1 to 20 carbon atoms among the monovalent organic groups having 1 to 40 carbon atoms represented by R⁰ and R¹ in the formula (1) can be suitably adopted.

A divalent hydrocarbon group having 1 to 10 carbon atoms such as a methanediyl group, an ethanediyl group, and a phenylene group, —O—, and a combination of them are preferable as R⁷, and a methanediyl group or a combination of a methanediyl group and —O— is more preferable.

It is preferred that the polymer [A1] as the compound [A] has a group represented by the formula (2-1) and the group is represented by formula (2-1-1) or (2-1-2). In the formula, * has the same meaning as in the formula (2-1).

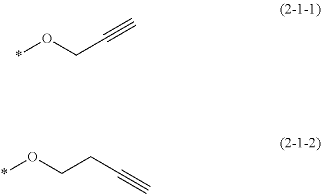

It is preferred that at least one of Ar¹, R⁰ or R¹ in the formula (1) preferably has a hydroxy group or the group (a). It is preferred that at least one of Ar¹ or R¹ has a hydroxy group or the group (a).

Ar¹, R⁰ and R¹ may have a substituent other than a hydroxy group and the group (α). Examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, aryloxy groups such as a phenoxy group and a naphthyloxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group and a carboxy group.

Examples of the repeating unit represented by the formula (1) include repeating units represented by formulas (1-1) to (1-32).

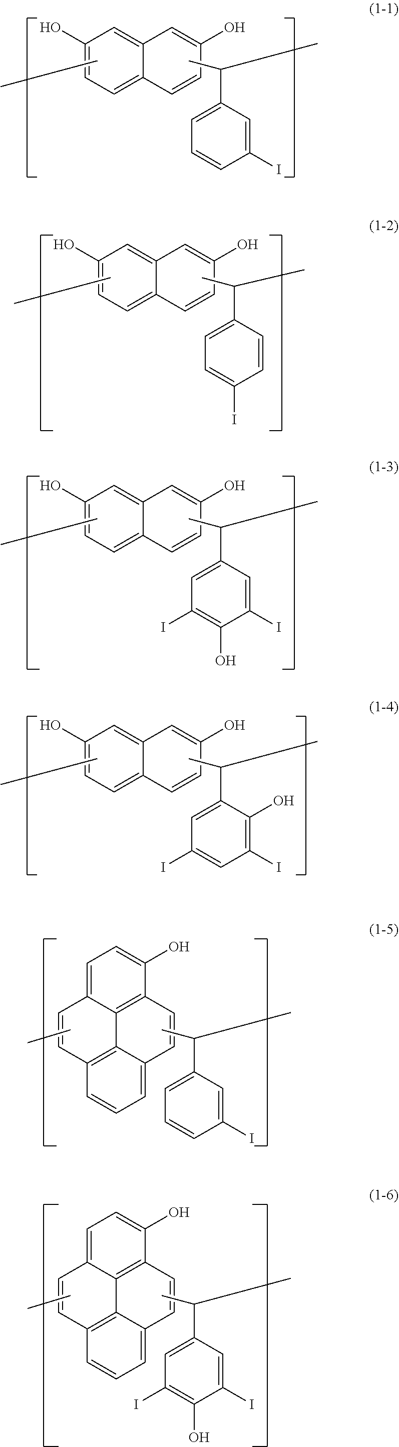

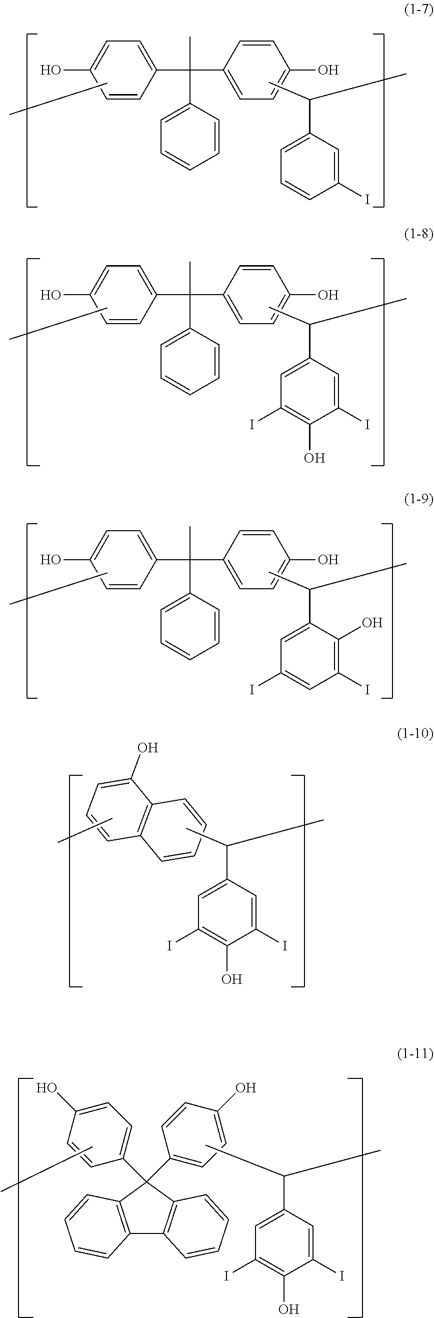

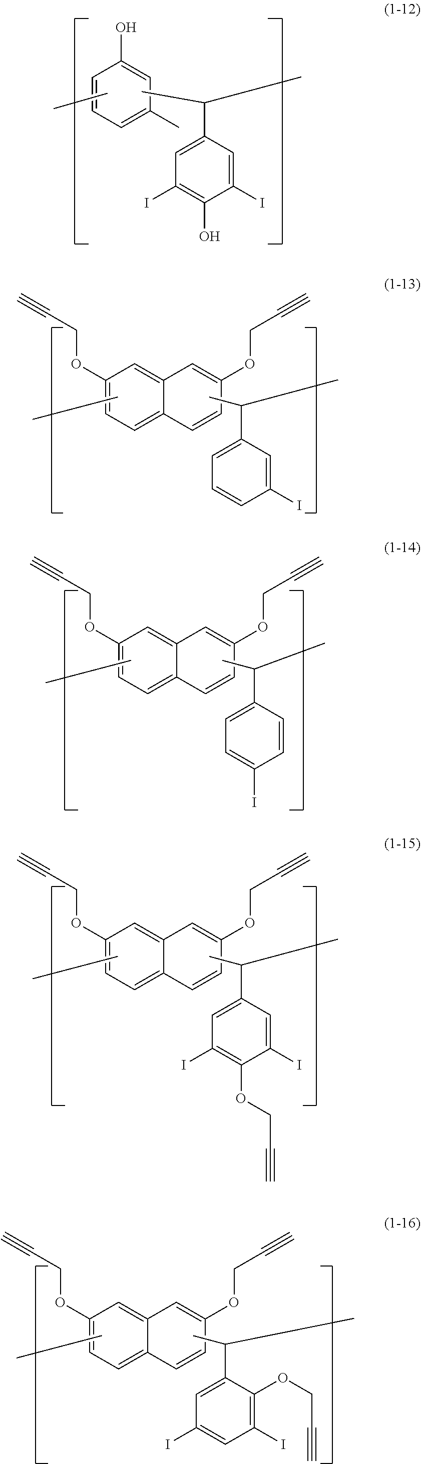

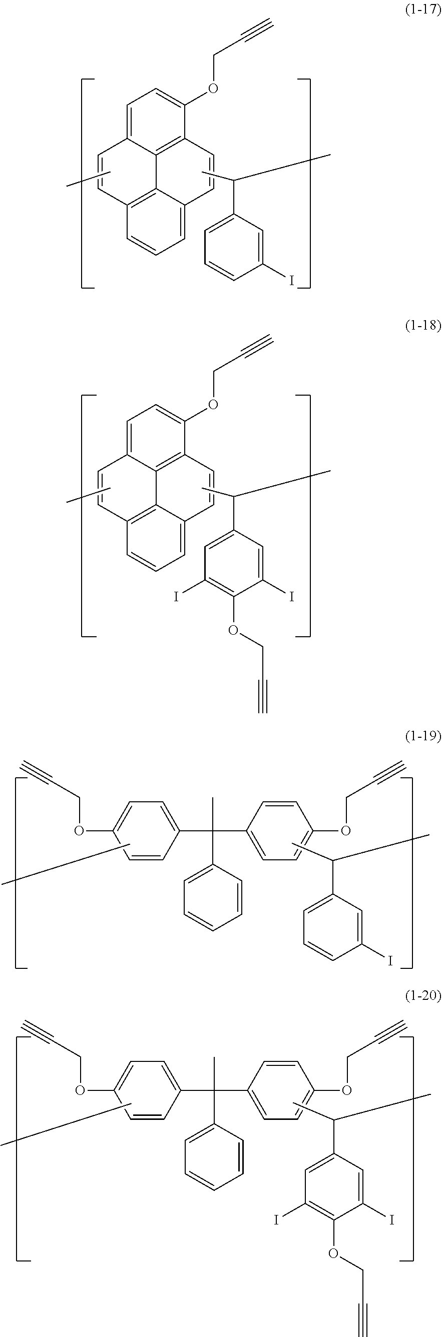

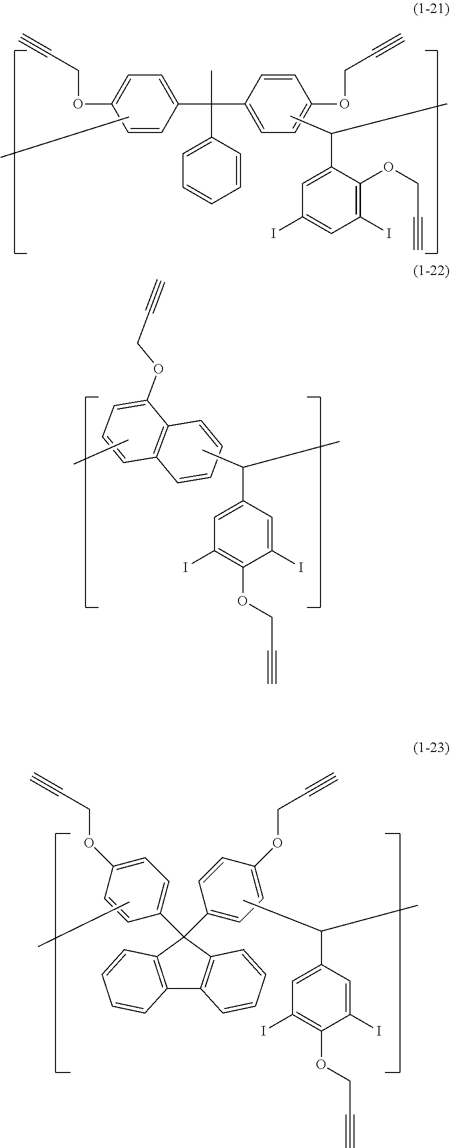

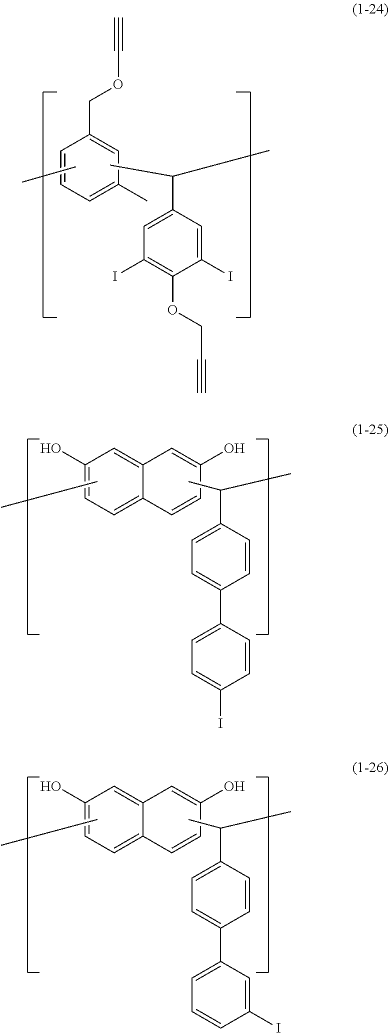

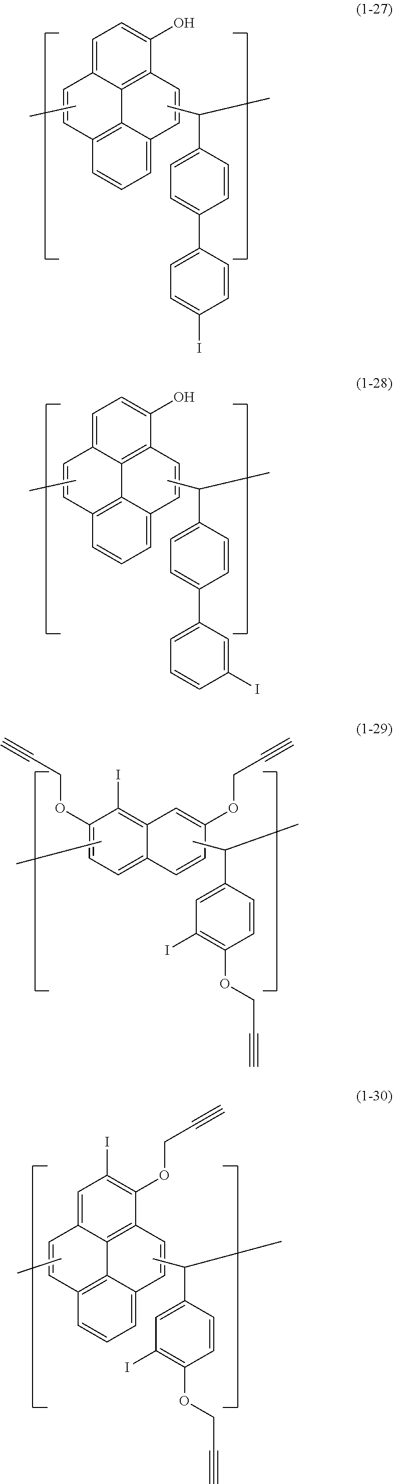

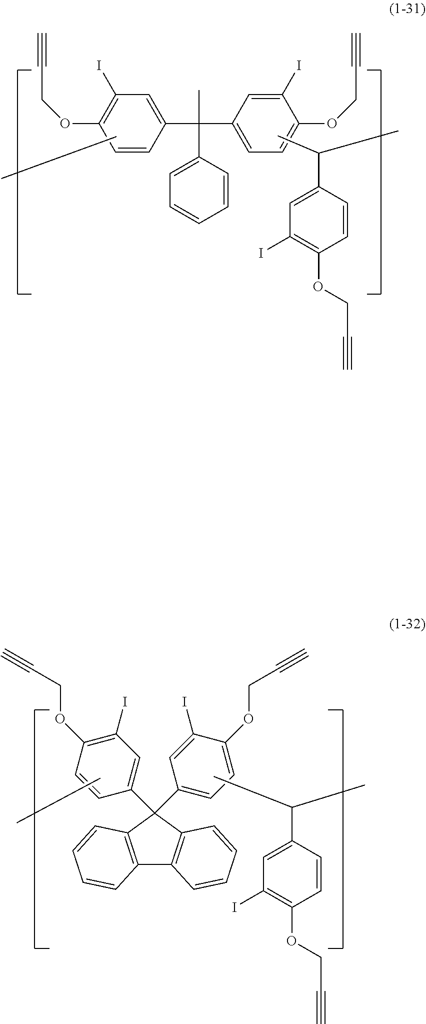

Among these, the repeating units represented by the formulas (1-1) to (1-24) are preferred.

The lower limit of the weight average molecular weight of the polymer [A1] is preferably 500, more preferably 1,000, still more preferably 1,500. The upper limit of the molecular weight is preferably 10,000, more preferably 7,000, still more preferably 5,000. The weight average molecular weight is measured as described in EXAMPLES.

### (Method for Manufacturing Polymer [A1])

The polymer [A1] can typically be manufactured by acid addition condensation of an aromatic ring compound as a precursor having a phenolic hydroxyl group that affords Ar¹ in the formula (1) and an aldehyde derivative as a precursor to afford R⁰ and R¹ in the formula (1). Furthermore, it is possible to manufacture the polymer [A1] having a group (α) introduced as a substituent by a nucleophilic substitution reaction of a phenolic hydroxyl group with a halogenated hydrocarbon corresponding to the group (α) represented by the formula (2-1) or (2-2). An acid catalyst is not particularly limited, and publicly known inorganic acids and organic acids can be used. After the reaction, the polymer [A1] can be obtained through separation, purification, drying, and the like. As the reaction solvent, the solvent [B] described later can be suitably employed.

### (Aromatic Ring-Containing Compound [A2])

The aromatic ring-containing compound [A2] is not particularly limited as long as it is a compound having an iodine atom and a molecular weight of 750 or more and 3000 or less (however, excluding compounds corresponding to the polymer [A1]). The lower limit of the molecular weight of the aromatic ring-containing compound [A2] is preferably 750, more preferably 950, still more preferably 1,050. The upper limit of the molecular weight is preferably 3000, more preferably 2500, still more preferably 2000.

The aromatic ring-containing compound [A2] is preferably a compound represented by formula (3).

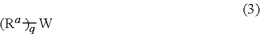

(In the formula (3),
W is a q-valent group containing a substituted or unsubstituted aromatic ring having 5 to 60 ring members,
R^{a} is a monovalent group containing an aromatic ring having 5 to 40 ring members,
q is an integer from 1 to 10, when q is 2 or more, a plurality of R^{a}s are the same as or different from each other, and
at least one of W or one R^{a} or a plurality of R^{a}s has an iodine atom).

In the formula (3), it is preferred that one R^{a} or a plurality of R^{a}s have an iodine atom, it is more preferred that at least one of a plurality of R^{a}s has an iodine atom, and it is still more preferred that all of a plurality of R^{a}s have an iodine atom.

As the aromatic ring having 5 to 60 ring members in W, an aromatic ring obtained by extending the aromatic ring having 5 to 40 ring members in Ar¹ of the formula (1) to an aromatic ring having 60 ring members can be suitably adopted. Examples of the q-valent group represented by W and containing a substituted or unsubstituted aromatic ring having 5 to 60 ring members include a group in which q hydrogen atoms are removed from the aromatic ring having 5 to 60 ring members. As the substituent in the case where W has a substituent, a hydroxy group, the group (a), and the substituents mentioned as the substituents other than these can be suitably adopted.

The aromatic ring of W is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring.

In a case where W has an iodine atom, it is preferred that at least one hydrogen atom of the aromatic ring in W is substituted with an iodine atom.

As the aromatic ring having 5 to 40 ring members in R^{a}, an aromatic ring having 5 to 40 ring members in Ar¹ of the formula (1) can be suitably adopted. Examples of the monovalent group containing an aromatic ring having 5 to 40 ring members, represented by R^{a}, include a group in which one hydrogen atom is removed from the aromatic ring having 5 to 40 ring members. The aromatic ring of R^{a} is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring. As the substituent in the case where R^{a} has a substituent, a hydroxy group, the group (α), and the substituents mentioned as the substituents other than these can be suitably adopted.

R^{a} is preferably a group represented by formula (3-1) or (3-2).

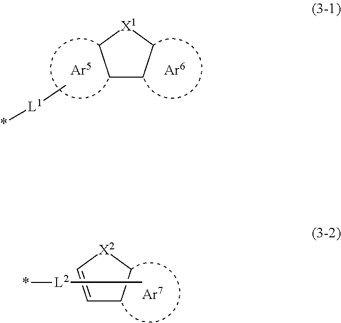

(In the formulas (3-1) and (3-2), X¹ and X² are each independently a group represented by formula (i), (ii), (iii) or (iv), Ar⁵, Ar⁶ and Ar⁷ are each independently a substituted or unsubstituted aromatic ring having 6 to 20 ring members that forms a condensed ring structure together with two adjacent carbon atoms in the formulas (3-1) and (3-2), L¹ and L² are each independently a single bond or a divalent organic group having an aromatic ring, and * is a bond with a carbon atom in W of the formula (3)).

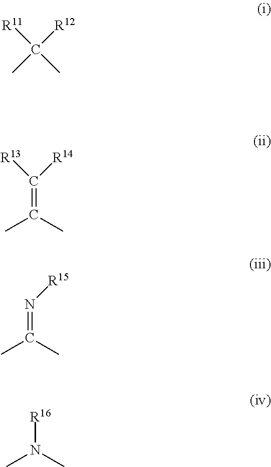

(In the formula (i), R¹¹ and R¹² are each independently a hydrogen atom or a monovalent organic group having 1 to 20 carbon atoms, and at least one of R¹¹ or R¹² has an iodine atom,
in the formula (ii), R¹³ is a hydrogen atom or a monovalent organic group having 1 to 20 carbon atoms, R¹⁴ is a monovalent organic group having 1 to 20 carbon atoms, and at least one of R¹³ or R¹⁴ has an iodine atom,
in the formula (iii), R¹⁵ is a monovalent organic group having 1 to 20 carbon atoms and having an iodine atom, and
in the formula (iv), R¹⁶ is a monovalent organic group having 1 to 20 carbon atoms and having a hydrogen atom or an iodine atom).

In the formulas (3-1) and (3-2), Ar⁵, Ar⁶ and Ar⁷ (hereinafter, sometimes referred to as “Ar⁵ to Ar⁷”) are each independently a substituted or unsubstituted aromatic ring having 6 to 20 ring members that forms a condensed ring structure together with two adjacent carbon atoms in the formulas (3-1) and (3-2). As the aromatic ring having 6 to 20 ring members in Ar⁵ to Ar⁷, aromatic rings corresponding to 6 to 20 ring members among the aromatic rings having 5 to 40 ring members in Ar¹ of the formula (1) can be suitably adopted.

As the substituent in the case where Ar⁵ to Ar⁷ have a substituent, a hydroxy group, the group (α), and the substituents mentioned as the substituents other than these can be suitably adopted.

Examples of the monovalent organic group having 1 to 20 carbon atoms represented by R¹¹, R¹², R¹³, R¹⁴, R¹⁵, and R¹⁶ (hereinafter, sometimes referred to as “R¹¹ to R¹⁶”) in the formulas (i), (ii), (iii), and (iv) include a group corresponding to 1 to 20 carbon atoms among the monovalent organic groups having 1 to 40 carbon atoms, represented by R⁰ and R¹ of the formula (1).

It is preferred that at least one of R¹¹ or R¹² in the formula (i), at least one of R¹³ or R¹⁴ in the formula (ii), R¹⁵ in the formula (iii), and R¹⁶ in the formula (iv) each have an aromatic ring having 5 to 40 ring members. As the aromatic ring having 5 to 40 ring members, the aromatic rings having 5 to 40 ring members in Ar¹ of the formula (1) can be suitably adopted. In this case, it is preferred that at least one hydrogen atom of the aromatic ring is substituted with an iodine atom. The number of iodine atoms on the aromatic ring is preferably an integer from 1 to 4, more preferably an integer from 1 to 3, still more preferably 1 or 2.

Suitable examples of the divalent organic group having an aromatic ring in L¹ and L² in the formulas (3-1) and (3-2) include a substituted or unsubstituted group in which two hydrogen atoms are removed from an aromatic ring having 5 to 40 ring members in Ar¹ of the formula (1) (hereinafter also referred to as “group (β)”). The divalent organic group having an aromatic ring represented by L¹ and L² may be a group formed by combining the group (β) with a group obtained by removing one hydrogen atom from a monovalent organic group having 1 to 20 carbon atoms, represented by R¹¹ to R¹⁶. As the divalent organic group having an aromatic ring, represented by L¹ and L², a substituted or unsubstituted arenediyl group having 6 to 12 ring members, a substituted or unsubstituted alkenediyl group having 2 to 10 carbon atoms, an alkynediyl group having 2 to 10 carbon atoms, or a combination thereof are preferred, a benzenediyl group, a naphthalenediyl group, an ethylenediyl group, an ethynediyl group, or a combination thereof is more preferred, and a benzenediyl group or a combination of a benzenediyl group with an ethynediyl group is still more preferred.

In the formulas (3-1) and (3-2), L¹ and L² are preferably single bonds.

Examples of the aromatic ring-containing compound [A2] include compounds represented by formulas (3-1) to (3-9). In the formulas, the number attached to the structure showing R indicates the molar ratio in the aromatic ring-containing compound [A2].

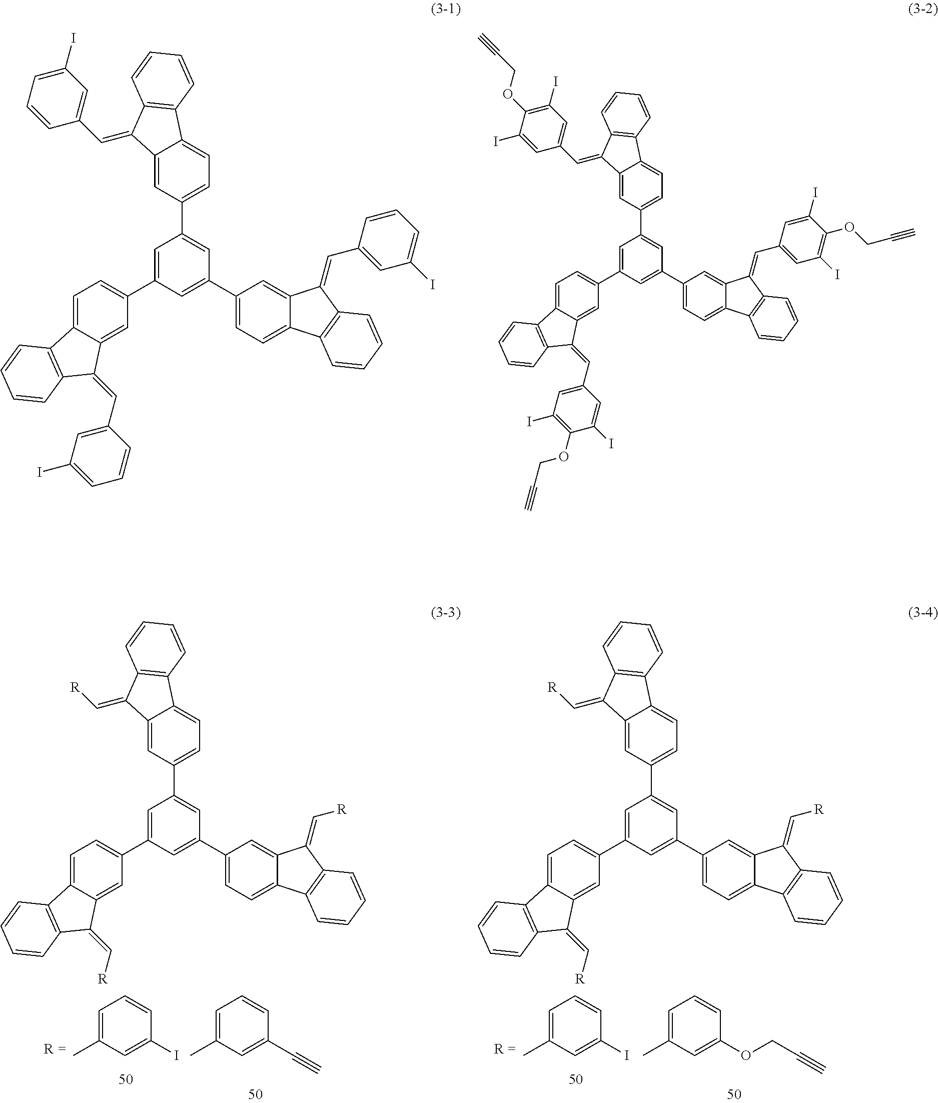

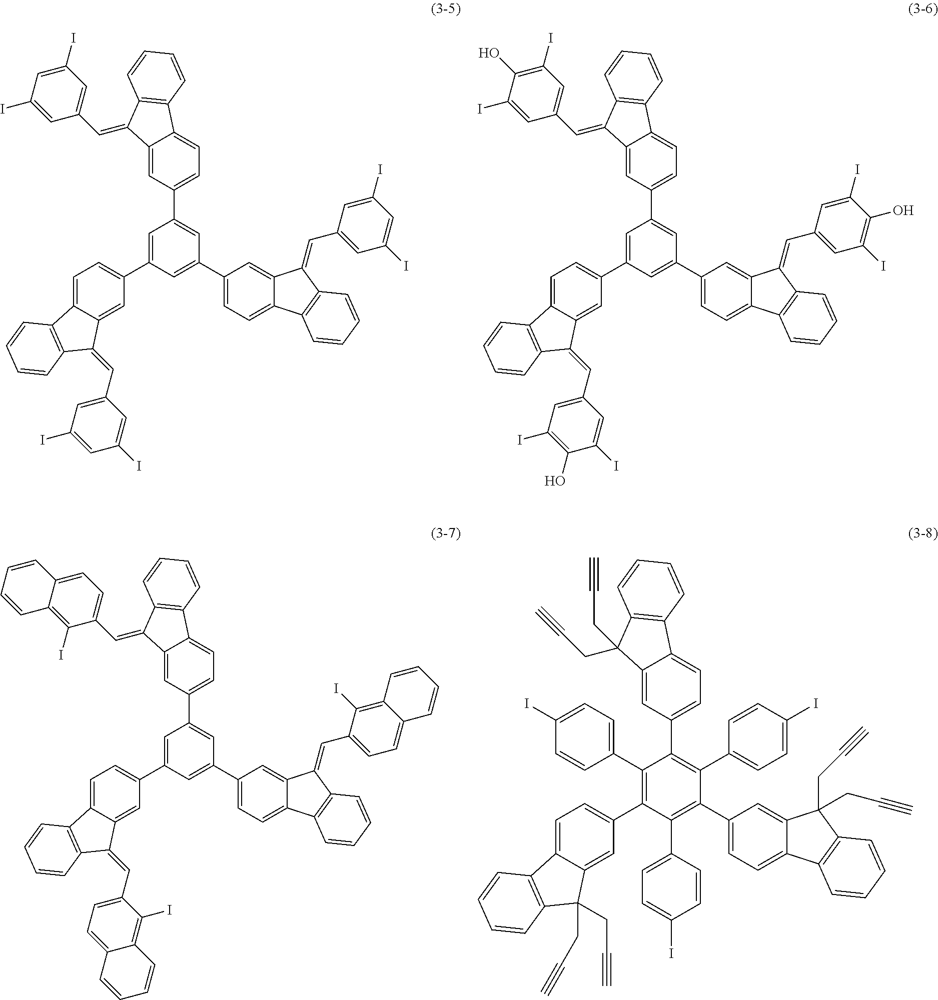

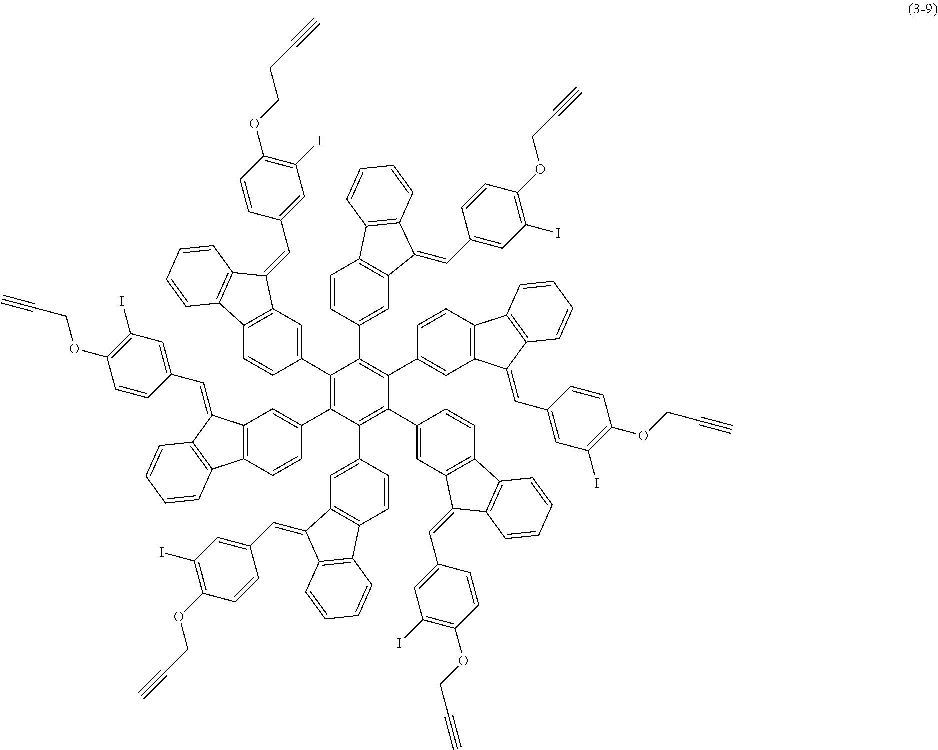 [SMILES: C#CCCOc1ccc(/C=C2\c3ccccc3-c3ccc(-c4c(-c5ccc6c(c5)/C(=C/c5ccc(OCC#C)c(I)c5)c5ccccc5-6)c(-c5ccc6c(c5)/C(=C/c5ccc(OCC#C)c(I)c5)c5ccccc5-6)c(-c5ccc6c(c5)/C(=C/c5ccc(OCC#C)c(I)c5)c5ccccc5-6)c(-c5ccc6c(c5)/C(=C/c5ccc(OCC#C)c(I)c5)c5ccccc5-6)c4-c4ccc5c(c4)/C(=C/c4ccc(OCC#C)c(I)c4)c4ccccc4-5)cc32)cc1I]

As the method for synthesizing the aromatic ring-containing compound [A2], typically, the aromatic ring-containing compound [A2] can be synthesized by preparing, for example, a ketone or alkyne-substituted fluorene as a starting material and conducting the cyclization reaction of the ketone moiety or alkyne moiety in the presence of a catalyst and the like. Other structures can also be synthesized by appropriately selecting the starting materials, the structure of the ketone body, and the like.

The content ratio of the compound (A) to the components other than the solvent in the composition for forming a resist underlayer film is 50% by mass or more. The lower limit of the content ratio is preferably 60% by mass, more preferably 70% by mass, still more preferably 80% by mass, particularly preferably 90% by mass. The upper limit of the content ratio is preferably 100% by mass (that is, the composition for forming a resist underlayer film contains only the compound [A] other than the solvent). In a case where the composition for forming a resist underlayer film contains an optional component, the upper limit of the content ratio is preferably 99% by mass, more preferably 98% by mass.

The lower limit of the content ratio of the compound [A] in the composition is preferably 0.01% by mass, more preferably 0.05% by mass, still more preferably 0.1% by mass, particularly preferably 0.5% by mass in the total mass of the compound [A] and the solvent [B]. The upper limit of the content ratio is preferably 30% by mass, more preferably 20% by mass, still more preferably 10% by mass, particularly preferably 5% by mass in the total mass of the compound [A] and the solvent [B].

### <Solvent [B]>

The solvent [B] is not particularly limited as long as it can dissolve or disperse the compound [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition is preferably 50% by mass, more preferably 60% by mass, still more preferably 70% by mass, particularly preferably 80% by mass. The upper limit of the content ratio is preferably 99.99% by mass, more preferably 99.98% by mass, still more preferably 99.9% by mass, particularly preferably 99.5% by mass.

### [Optional Component]

The composition for forming a resist underlayer film may contain an optional component as long as the effects of the present disclosure are not impaired. Examples of the optional component include an acid generator, a crosslinking agent, a surfactant, and a sensitizer. As the optional component, a polymer different from the polymer [A1] and an aromatic ring-containing compound different from the aromatic ring-containing compound [A2] may be contained. The optional component may be used singly or two or more kinds thereof may be used in combination.

### [Method for Preparing Composition]

The composition for forming a resist underlayer film can be prepared by mixing the compound [A], the solvent [B] and, as necessary, an optional component in a prescribed ratio and preferably filtering the resulting mixture through a membrane filter having a pore size of 0.5 μm or less and the like.

### [Use of Composition for Forming Resist Underlayer Film]

The composition for forming a resist underlayer film is a composition for forming an underlayer film of a resist film to be exposed to extreme ultraviolet rays as described above. Examples of the composition for forming a resist film include a positive or negative chemically amplified resist composition containing a radiation-sensitive acid generator, a positive resist composition containing an alkali-soluble resin and a quinonediazide-based photosensitizer, a negative resist composition containing an alkali-soluble resin and a crosslinking agent, and a metal-containing resist composition containing a metal such as tin, zirconium, or hafnium. The underlayer film formed from the composition contains iodine atoms derived from the compound [A], and therefore has a high efficiency in generating secondary electrons through absorption of extreme ultraviolet rays. As a result, when exposed to extreme ultraviolet rays, a sufficient difference in solubility occurs in the interface region of the organic resist film on the underlayer film side, or the insolubilization of the metal-containing resist film is promoted, and thus trailing of the pattern at the bottom of the resist film can be suppressed and the rectangularity of the resist pattern can be secured. The lower limit of the content ratio of the metal or metal compound to the components other than the solvent in the metal-containing resist composition is preferably 50% by mass, more preferably 70% by mass, still more preferably 80% by mass, particularly preferably 85% by mass. The upper limit of the content ratio is, for example, 100% by mass or 95% by mass.

In the case of a metal-containing resist film, when the metal-containing resist film components intermix with the underlayer film, residues (defects) are generated after etching. In the underlayer film formed from the composition, the compound [A] has an aromatic ring and is capable of forming a film having a high density by a crosslinking reaction and a hydrophobicity of iodine atoms, therefore, the intermixing is suppressed, and as a result, a desired pattern with suppressed defects can be formed.

### <<Method for Manufacturing Semiconductor Substrate>>

The method for manufacturing a semiconductor substrate includes a step of directly or indirectly applying a composition for forming a resist underlayer film to a substrate (this step is hereinafter also referred to as “application step (I)”); a step of applying a composition for forming a resist film to the resist underlayer film formed by the step of applying a composition for forming a resist underlayer film (this step is hereinafter also referred to as “application step (II)”); a step of exposing the resist film formed by the step of applying a composition for forming a resist film to extreme ultraviolet rays (this step is hereinafter also referred to as “exposure step”); and a step of developing at least the exposed resist film (this step is hereinafter also referred to as “development step”).

By the method for manufacturing a semiconductor substrate, a resist underlayer film excellent in resist pattern rectangularity can be formed by using the composition for forming a resist underlayer film in the application step (I), so that a semiconductor substrate having a favorable pattern shape can be manufactured.

The method for manufacturing a semiconductor substrate may further include, as necessary, a step of directly or indirectly forming a silicon-containing film on the substrate (this step is hereinafter also referred to as “silicon-containing film formation step”) before the application step (I).

Hereinafter, the composition for forming a resist underlayer film to be used in the method for manufacturing a semiconductor substrate, and the respective steps in the case of including the silicon-containing film formation step, which is an optional step, will be described.

### [Silicon-Containing Film Forming Step]

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to a substrate is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 15 nm. The upper limit of the average thickness is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on a substrate include a case where the silicon-containing film is formed on a low dielectric insulating film or an organic underlayer film formed on the substrate, a metal hard mask (TiO₂ or the like), or a carbon film by the CVD method.

### [Application Step (I)]

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

When the composition for forming a resist underlayer film is applied directly to the substrate, the silicon-containing film formation step may be omitted.

Next, the coating film formed by the application is heated. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 100° C., more preferably 150° C., and still more preferably 200° C. The upper limit of the heating temperature is preferably 400° C., and more preferably 350° C., and still more preferably 280° C. The lower limit of the heating time is preferably 15 seconds, and more preferably 30 seconds. The upper limit of the time is preferably 1,200 seconds, and more preferably 600 seconds.

After the applying step (I), the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1,500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 0.5 nm, more preferably 1 nm, still more preferably 2 nm. The upper limit of the average thickness is 15 nm, preferably 12 nm, more preferably 10 nm, still more preferably 8 nm, particularly preferably 6 nm. The average thickness is measured as described in Examples.

### [Application Step (II)]

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step in more detail, for example, a composition for forming a resist film is applied such that a resist film formed has a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

The composition for forming a resist film used in this step is suitably a composition that is exposed to extreme ultraviolet rays, and examples of the composition include a positive or negative chemically amplified resist composition that contains a radiation-sensitive acid generator and a metal-containing resist composition that contains a metal such as tin, zirconium, or hafnium.

### [Exposure Step]

In this step, a resist film formed in the step of applying a composition for forming a resist film is exposed to extreme ultraviolet (EUV) rays. The exposure conditions can be appropriately determined depending on the type of the composition for forming a resist film to be used, and the like.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the duration of PEB is preferably 600 seconds, more preferably 300 seconds.

### [Development Step]

In this step, the exposed resist film is developed. At this time, a part of the resist underlayer film may also be developed. Examples of the developer to be used for the development include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, an aqueous TMAH solution is preferable, and a 2.38% by mass aqueous TMAH solution is more preferable.

Examples of the organic solvent developer in the case of performing organic solvent development include the same developers as those disclosed as the examples of the solvent [B] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development.

### [Etching Step]

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When etching is performed multiple times, for example, etching is sequentially performed in the order of the silicon-containing film and the substrate. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₃, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

In a case where the silicon-containing film remains on the substrate or the like after the substrate pattern formation, the silicon-containing film can be removed by performing a removal step.

### EXAMPLES

Hereinbelow, the present invention will specifically be described on the basis of examples, but is not limited to these examples.

### [Weight-Average Molecular Weight (Mw)]

The Mw of a polymer was measured by gel permeation chromatography (detector: differential refractometer) with monodisperse polystyrene standards using GPC columns (“G2000HXL”×2, “G3000HXL”×1 and “G4000HXL”×1) manufactured by Tosoh Corporation under the following analysis conditions: flow rate: 1.0 mL/min; elution solvent: tetrahydrofuran; column temperature: 40° C.

### [Average Thickness of Film]

The average thickness of a film was determined as a value attained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### [Introduction Rate of Propargyl Group]

The introduction rate of a propargyl group was determined by ¹³C-NMR analysis using a JNM-ECX400P manufactured by JEOL Ltd. and a measurement sample prepared by dissolving the compound [A] in DMSO-d₆ solvent containing 5% chromium acetoacetate.

### [Synthesis Example 1](Synthesis of Polymer (A-1))

A reaction vessel was charged with 10.0 g of 2,7-dihydroxynaphthalene, 14.5 g of 3-iodobenzaldehyde, and 65.0 g of 1-butanol in a nitrogen atmosphere, and stirring was performed to dissolve the compounds. A 1-butanol solution (9.0 g) of 5.9 g of p-toluenesulfonic acid monohydrate was added into the reaction vessel, and the mixture was heated to 110° C., and the reaction was conducted for 12 hours. After completion of the reaction, the reaction solution was transferred to a separatory funnel, 100 g of methyl isobutyl ketone and 200 g of water were added thereto, and the organic phase was washed. After the aqueous phase was separated, the obtained organic phase was washed several times with water. Thereafter, the organic phase was concentrated using an evaporator, and the residue was dropped into 100 g of methanol to obtain a precipitate. The precipitate was collected by suction filtration and washed several times with 50 g of methanol. Thereafter, the washed product was dried in a vacuum dryer at 60° C. for 12 hours to obtain a polymer (A-1) having a repeating unit represented by formula (A-1). The Mw of the polymer (A-1) was 2390.

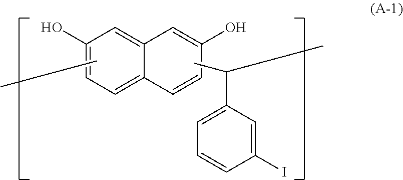

### [Synthesis Example 2] (Synthesis of Polymer (A-2))

A polymer (A-2) having a repeating unit represented by formula (A-2) was obtained by conducting the reaction under the same conditions as in [Synthesis Example 1], except that 14.5 g of 4-iodobenzaldehyde was used instead of 14.5 g of 3-iodobenzaldehyde. The Mw of the polymer (A-2) was 2500.

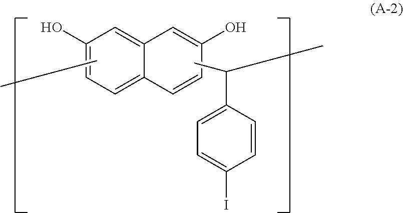

### [Synthesis Example 3] (Synthesis of Polymer (A-3))

A polymer (A-3) having a repeating unit represented by formula (A-3) was obtained by conducting the reaction under the same conditions as in [Synthesis Example 1], except that 23.3 g of 3,5-diiodo-4-hydroxybenzaldehyde was used instead of 14.5 g of 3-iodobenzaldehyde. The Mw of the polymer (A-3) was 2900.

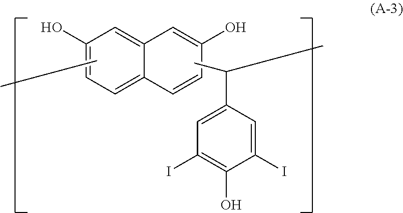

### [Synthesis Example 4] (Synthesis of Polymer (A-4))

A polymer (A-4) having a repeating unit represented by formula (A-4) was obtained by conducting the reaction under the same conditions as in [Synthesis Example 1], except that 14.5 g of 3,5-diiodo-2-hydroxybenzaldehyde was used instead of 23.3 g of 3-iodobenzaldehyde. The Mw of the polymer (A-4) was 3100.

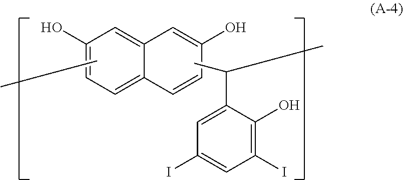

### [Synthesis Example 5] (Synthesis of Polymer (A-5))

A polymer (A-5) having a repeating unit represented by formula (A-5) was obtained by conducting the reaction under the same conditions as in [Synthesis Example 1], except that 13.7 g of 1-hydroxypyrene was used instead of 10.0 g of 2,7-dihydroxynaphthalene. The Mw of the polymer (A-5) was 3400.

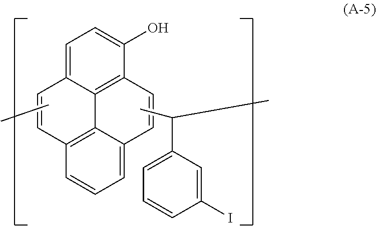

### [Synthesis Example 6] (Synthesis of Polymer (A-6))

A polymer (A-6) having a repeating unit represented by formula (A-6) was obtained by conducting the reaction under the same conditions as in [Synthesis Example 3], except that 13.7 g of 1-hydroxypyrene was used instead of 10.0 g of 2,7-dihydroxynaphthalene. The Mw of the polymer (A-6) was 3200.

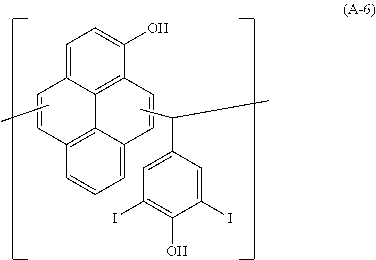

### [Synthesis Example 7] (Synthesis of Polymer (A-7))

A polymer (A-7) having a repeating unit represented by formula (A-7) was obtained by conducting the reaction under the same conditions as in [Synthesis Example 1], except that 18.1 g of 1,1-bis(4-hydroxyphenyl)-1-phenylethane was used instead of 10.0 g of 2,7-dihydroxynaphthalene. The Mw of the polymer (A-7) was 3000.

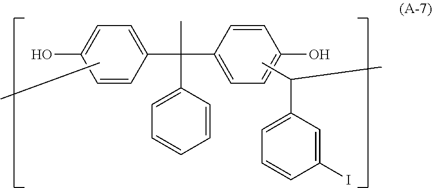

### [Synthesis Example 8] (Synthesis of Polymer (A-8))

A polymer (A-8) having a repeating unit represented by formula (A-8) was obtained by conducting the reaction under the same conditions as in [Synthesis Example 3], except that 18.1 g of 1,1-bis(4-hydroxyphenyl)-1-phenylethane was used instead of 10.0 g of 2,7-dihydroxynaphthalene. The Mw of the polymer (A-8) was 2310.

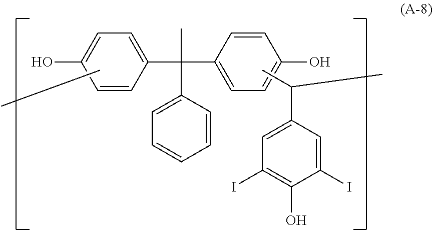

### [Synthesis Example 9] (Synthesis of Polymer (A-9))

A polymer (A-9) having a repeating unit represented by formula (A-9) was obtained by conducting the reaction under the same conditions as in [Synthesis Example 4], except that 18.1 g of 1,1-bis(4-hydroxyphenyl)-1-phenylethane was used instead of 10.0 g of 2,7-dihydroxynaphthalene. The Mw of the polymer (A-9) was 2890.

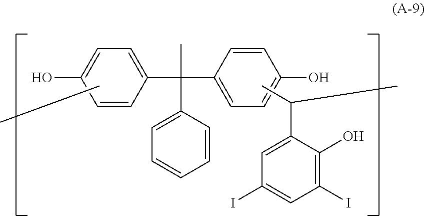

### [Synthesis Example 10] (Synthesis of Polymer (A-10))

A polymer (A-10) having a repeating unit represented by formula (A-10) was obtained by conducting the reaction under the same conditions as in [Synthesis Example 3], except that 9.0 g of 1-naphthol was used instead of 10.0 g of 2,7-dihydroxynaphthalene. The Mw of the polymer (A-10) was 2000.

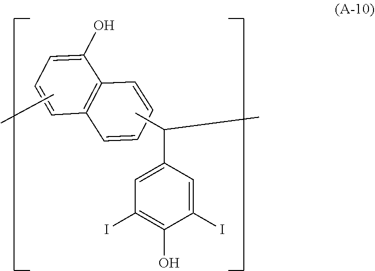

### [Synthesis Example 11] (Synthesis of Polymer (A-11))

A polymer (A-11) having a repeating unit represented by formula (A-11) was obtained by conducting the reaction under the same conditions as in [Synthesis Example 3], except that 21.9 g of 9,9-bis(4-hydroxyphenyl)fluorene was used instead of 10.0 g of 2,7-dihydroxynaphthalene. The Mw of the polymer (A-11) was 3100.

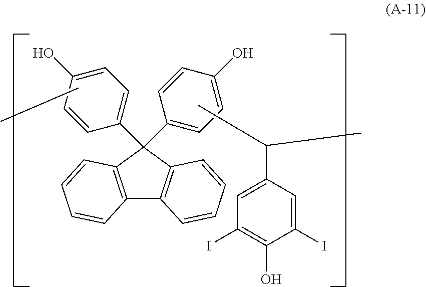

### [Synthesis Example 12] (Synthesis of Polymer (A-12))

A polymer (A-12) having a repeating unit represented by formula (A-12) was obtained by conducting the reaction under the same conditions as in [Synthesis Example 3], except that 6.8 g of m-cresol was used instead of 10.0 g of 2,7-dihydroxynaphthalene. The Mw of the polymer (A-12) was 1980.

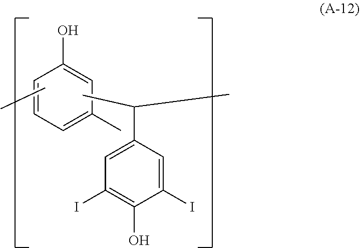

### [Synthesis Example 13] (Synthesis of Polymer (A-13))

Into a reaction vessel, 5.0 g of the polymer (A-1), 30.0 g of methyl isobutyl ketone, 12.0 g of methanol, and 12.0 g of tetramethylammonium hydroxide (25% aqueous solution) were added, and the mixture was stirred at room temperature for several minutes to dissolve the polymer (A-1). Added was 3.8 g of propargyl bromide, and the mixture was heated from room temperature to 40° C. and reacted for 4 hours. After completion of the reaction, the reaction solution was transferred to a separatory funnel, 100 g of methyl isobutyl ketone and 200 g of a 5% aqueous oxalic acid solution were added, and the organic phase was separated. The organic phase was washed with water several times, and then the obtained organic phase was concentrated using an evaporator and added dropwise to 150 g of methanol to obtain a precipitate. The precipitate was collected by suction filtration and washed several times with 50 g of methanol. Thereafter, the washed product was dried in a vacuum dryer at 60° C. for 12 hours to obtain a polymer (A-13) having a repeating unit represented by formula (A-13). The Mw of the polymer (A-13) was 3,115, and the introduction rate of a propargyl group in the polymer (A-13) was 83% with respect to all the hydroxy groups.

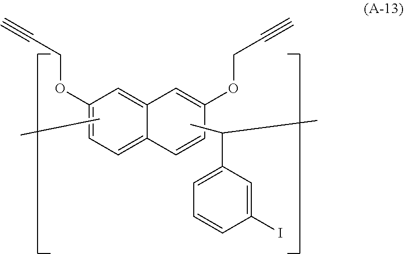

### [Synthesis Example 14] (Synthesis of Polymer (A-14))

A polymer (A-14) having a repeating unit represented by formula (A-14) was obtained by conducting the reaction under the same conditions as in [Synthesis Example 13], except that 5.0 g of polymer (A-2) was used instead of 5.0 g of polymer (A-1). The Mw of the polymer (A-14) was 3,520, and the introduction rate of a propargyl group in the polymer (A-14) was 90% with respect to all the hydroxy groups.

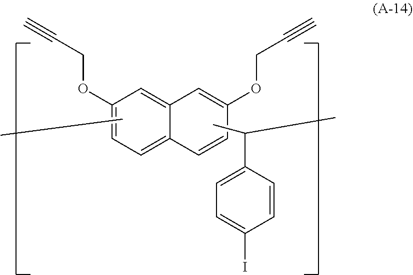

### [Synthesis Example 15] (Synthesis of Polymer (A-15))

A polymer (A-15) having a repeating unit represented by formula (A-15) was obtained by conducting the reaction under the same conditions as in [Synthesis Example 13], except that 6.9 g of polymer (A-3) was used instead of 5.0 g of polymer (A-1). The Mw of the polymer (A-15) was 3700, and the introduction rate of a propargyl group in the polymer (A-15) was 87% with respect to all the hydroxy groups.

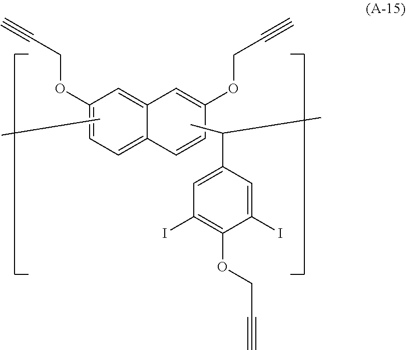

### [Synthesis Example 16] (Synthesis of Polymer (A-16))

A polymer (A-16) having a repeating unit represented by formula (A-16) was obtained by conducting the reaction under the same conditions as in [Synthesis Example 13], except that 6.9 g of polymer (A-4) was used instead of 5.0 g of polymer (A-1). The Mw of the polymer (A-16) was 4070, and the introduction rate of a propargyl group in the polymer (A-16) was 76% with respect to all the hydroxy groups.

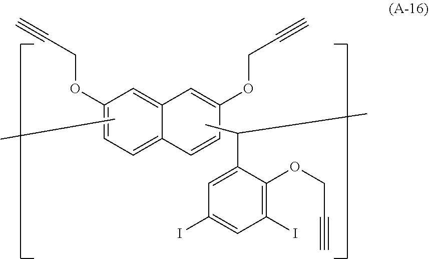

### [Synthesis Example 17] (Synthesis of Polymer (A-17))

A polymer (A-17) having a repeating unit represented by formula (A-17) was obtained by conducting the reaction under the same conditions as in [Synthesis Example 13], except that 5.8 g of polymer (A-5) was used instead of 5.0 g of polymer (A-1). The Mw of the polymer (A-17) was 3960, and the introduction rate of a propargyl group in the polymer (A-17) was 71% with respect to all the hydroxy groups.

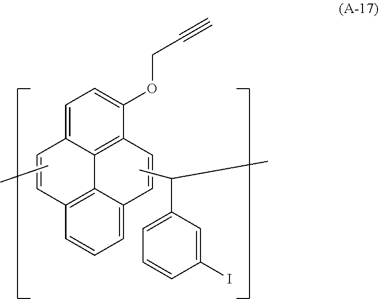

### [Synthesis Example 18] (Synthesis of Polymer (A-18))

A polymer (A-18) having a repeating unit represented by formula (A-18) was obtained by conducting the reaction under the same conditions as in [Synthesis Example 13], except that 7.7 g of polymer (A-6) was used instead of 5.0 g of polymer (A-1). The Mw of the polymer (A-18) was 3835, and the introduction rate of a propargyl group in the polymer (A-18) was 92% with respect to all the hydroxy groups.

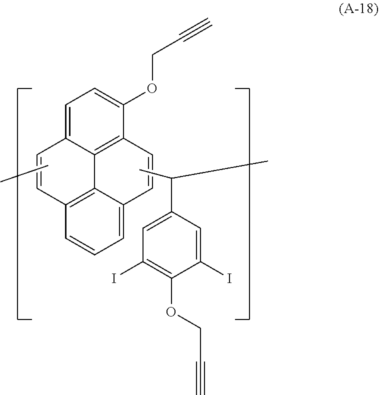

### [Synthesis Example 19] (Synthesis of Polymer (A-19))

A polymer (A-19) having a repeating unit represented by formula (A-19) was obtained by conducting the reaction under the same conditions as in [Synthesis Example 13], except that 6.8 g of polymer (A-7) was used instead of 5.0 g of polymer (A-1). The Mw of the polymer (A-19) was 4110, and the introduction rate of a propargyl group in the polymer (A-19) was 78% with respect to all the hydroxy groups.

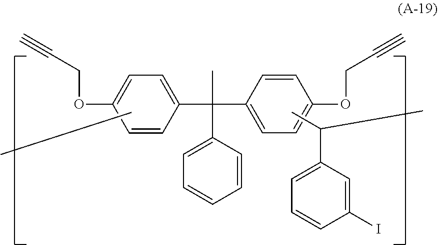

### [Synthesis Example 20] (Synthesis of Polymer (A-20))

A polymer (A-20) having a repeating unit represented by formula (A-20) was obtained by conducting the reaction under the same conditions as in [Synthesis Example 13], except that 8.7 g of polymer (A-8) was used instead of 5.0 g of polymer (A-1). The Mw of the polymer (A-20) was 2900, and the introduction rate of a propargyl group in the polymer (A-20) was 90% with respect to all the hydroxy groups.

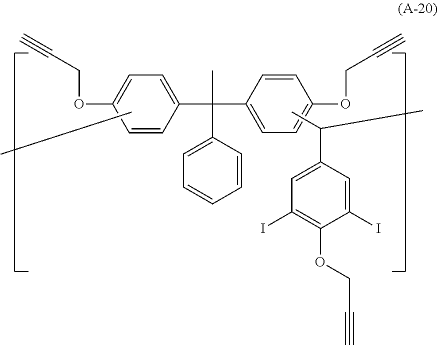

### [Synthesis Example 21] (Synthesis of Polymer (A-21))

A polymer (A-21) having a repeating unit represented by formula (A-21) was obtained by conducting the reaction under the same conditions as in [Synthesis Example 13], except that 8.7 g of polymer (A-9) was used instead of 5.0 g of polymer (A-1). The Mw of the polymer (A-21) was 3750, and the introduction rate of a propargyl group in the polymer (A-21) was 81% with respect to all the hydroxy groups.

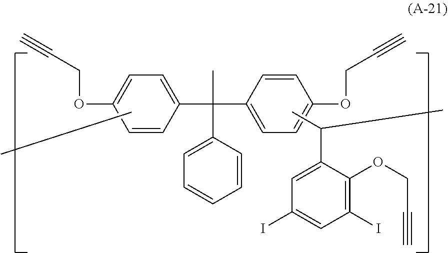

### [Synthesis Example 22] (Synthesis of Polymer (A-22))

A polymer (A-22) having a repeating unit represented by formula (A-22) was obtained by conducting the reaction under the same conditions as in [Synthesis Example 13], except that 6.7 g of polymer (A-10) was used instead of 5.0 g of polymer (A-1). The Mw of the polymer (A-22) was 4290, and the introduction rate of a propargyl group in the polymer (A-22) was 70% with respect to all the hydroxy groups.

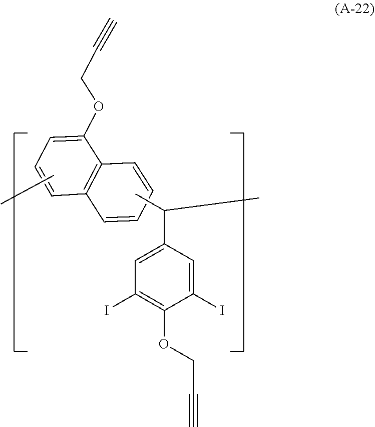

### [Synthesis Example 23] (Synthesis of Polymer (A-23))

A polymer (A-23) having a repeating unit represented by formula (A-23) was obtained by conducting the reaction under the same conditions as in [Synthesis Example 13], except that 9.5 g of polymer (A-11) was used instead of 5.0 g of polymer (A-1). The Mw of the polymer (A-23) was 4300, and the introduction rate of a propargyl group in the polymer (A-23) was 74% with respect to all the hydroxy groups.

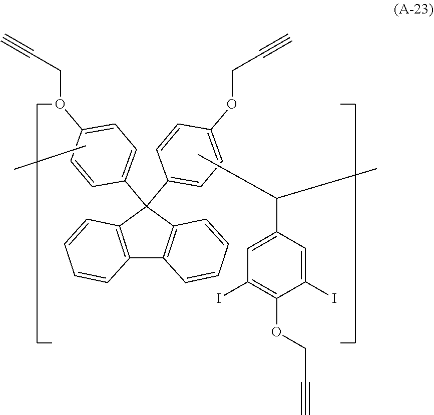

### [Synthesis Example 24] (Synthesis of Polymer (A-24))

A polymer (A-24) having a repeating unit represented by formula (A-24) was obtained by conducting the reaction under the same conditions as in [Synthesis Example 13], except that 6.2 g of polymer (A-12) was used instead of 5.0 g of polymer (A-1). The Mw of the polymer (A-24) was 2290, and the introduction rate of a propargyl group in the polymer (A-24) was 77% with respect to all the hydroxy groups.

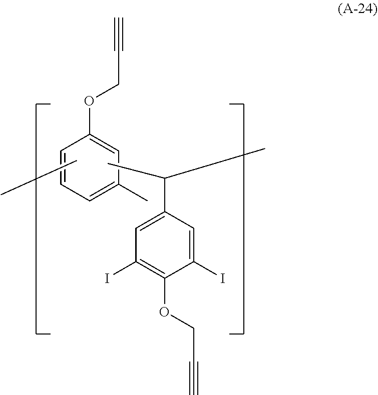

### [Synthesis Example 25] (Synthesis of Compound (A-25))

In a nitrogen atmosphere, 10.0 g of 1,3,5-benzenetriyltris-9H-fluorene, 22.7 g of 3-iodobenzaldehyde, and 140.0 g of tetrahydrofuran were added into a reaction vessel and suspended. Added were 46.0 g of 25% tetramethylammonium hydroxide and 1.7 g of tetrabutylammonium bromide, and the reaction was conducted at 60° C. for 4 hours. After completion of the reaction, 300.0 g of methyl isobutyl ketone and 200.0 g of a 5% aqueous oxalic acid solution were added and the organic phase was separated. The organic phase was washed with water several times, and then the obtained organic phase was concentrated using an evaporator and added dropwise to 300 g of methanol to obtain a precipitate. The precipitate was collected by suction filtration and washed several times with 50.0 g of methanol. Thereafter, the washed product was dried in a vacuum dryer at 60° C. for 12 hours to obtain a compound (A-25) represented by formula (A-25).

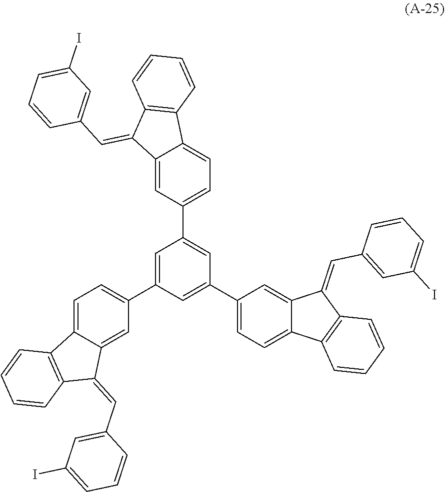 [SMILES: Ic1cccc(/C=C2\c3ccccc3-c3ccc(-c4cc(-c5ccc6c(c5)/C(=C/c5cccc(I)c5)c5ccccc5-6)cc(-c5ccc6c(c5)/C(=C/c5cccc(I)c5)c5ccccc5-6)c4)cc32)c1]

### [Synthesis Example 26] (Synthesis of Compound (A-26))

In a nitrogen atmosphere, 10.0 g of 1,3,5-benzenetriyltris-9H-fluorene, 36.7 g of 3,5-diiodo-4-hydroxybenzaldehyde, and 180.0 g of tetrahydrofuran were added into a reaction vessel and suspended. Added was 2.6 g of 1,8-diazabicyclo[5.4.0]-7-undecene, and the reaction was conducted at 100° C. for 8 hours. After completion of the reaction, 300.0 g of methyl isobutyl ketone and 200.0 g of a 5% aqueous oxalic acid solution were added and the organic phase was separated. The organic phase was washed with water several times, and then the obtained organic phase was concentrated using an evaporator and added dropwise to 300 g of methanol to obtain a precipitate. The precipitate was collected by suction filtration and washed several times with 50.0 g of methanol. Thereafter, the washed product was dried in a vacuum dryer at 60° C. for 12 hours. To 10.0 g of the obtained compound, 50.0 g of methyl isobutyl ketone, 20.0 g of methanol, and 7.3 g of tetramethylammonium hydroxide (25% aqueous solution) were added, and the mixture was stirred at room temperature for several minutes. Added was 2.4 g of propargyl bromide, and the mixture was heated from room temperature to 40° C. and reacted for 4 hours. After completion of the reaction, the reaction solution was transferred to a separatory funnel, 200 g of methyl isobutyl ketone and 200 g of a 5% aqueous oxalic acid solution were added, and the organic phase was separated. The organic phase was washed with water several times, and then the obtained organic phase was concentrated using an evaporator and added dropwise to 300 g of methanol to obtain a precipitate. The precipitate was collected by suction filtration and washed several times with 50 g of methanol. Thereafter, the washed product was dried in a vacuum dryer at 60° C. for 12 hours to obtain a compound (A-26) represented by formula (A-26). The introduction rate of a propargyl group in the compound (A-26) was 82% with respect to all the hydroxy groups.

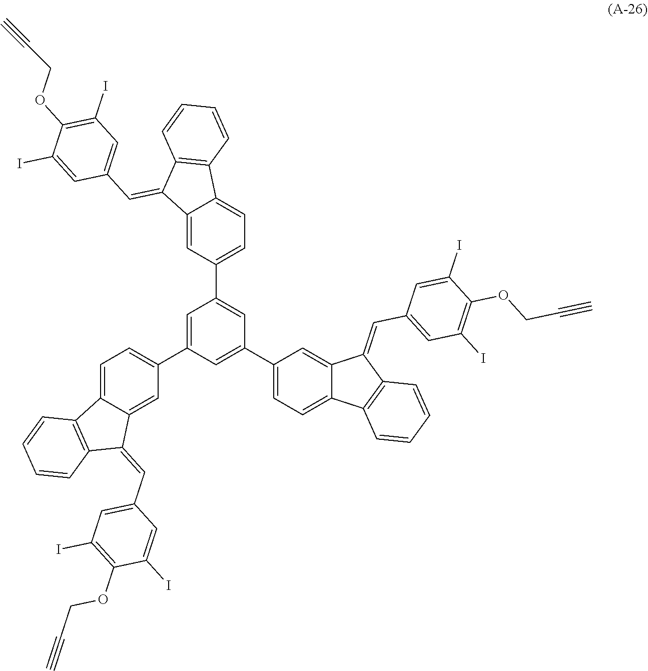 [SMILES: C#CCOc1c(I)cc(/C=C2\c3ccccc3-c3ccc(-c4cc(-c5ccc6c(c5)/C(=C/c5cc(I)c(OCC#C)c(I)c5)c5ccccc5-6)cc(-c5ccc6c(c5)/C(=C/c5cc(I)c(OCC#C)c(I)c5)c5ccccc5-6)c4)cc32)cc1I]

### [Synthesis Example 27] (Synthesis of Compound (A-27))

A compound (A-27) represented by formula (A-27) was obtained by conducting the reaction under the same conditions as in [Synthesis Example 25], except that a mixture of 11.3 g of 3-iodobenzaldehyde and 6.4 g of 3-ethynylbenzaldehyde was used instead of 22.7 g of 3-iodobenzaldehyde. In the formula, the number attached to the structure showing R indicates the molar ratio in the compound (A-27).

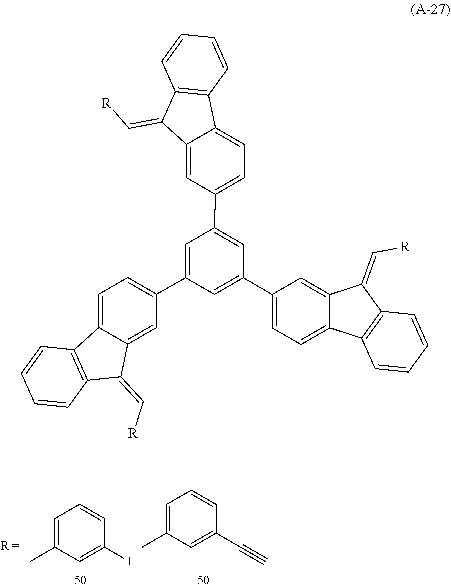

### [Synthesis Example 28] (Synthesis of Compound (A-28))

A compound (A-28) represented by formula (A-28) was obtained by conducting the reaction under the same conditions as in [Synthesis Example 26], except that a mixture of 11.3 g of 3-iodobenzaldehyde and 6.0 g of 3-hydroxybenzaldehyde was used instead of 36.7 g of 3,5-diiodo-4-hydroxybenzaldehyde. In the formula, the number attached to the structure showing R indicates the molar ratio in the compound (A-28). The introduction rate of a propargyl group in the compound (A-28) was 92% with respect to all the hydroxy groups.

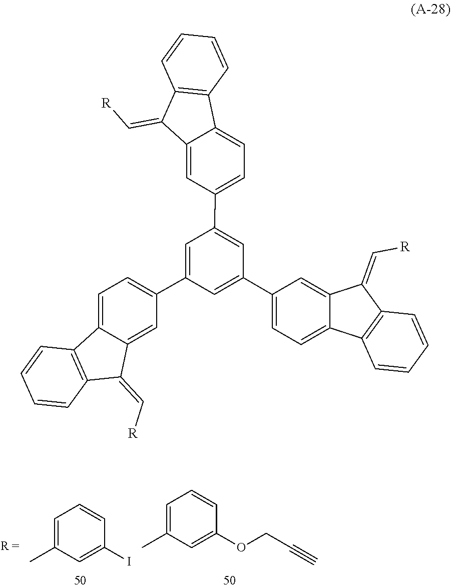

### [Comparative Example] (Synthesis of Polymer (X-1))

In a nitrogen atmosphere, 7.0 g of glycidyl methacrylate, 1.6 g of 2,2′-azobis(2,4-dimethylvaleronitrile), and 2.0 g of methyl isobutyl ketone were added into a reaction vessel and dissolved uniformly. Thereafter, the temperature was raised to 80° C. and the mixture was heated for 6 hours to conduct the reaction. The obtained reaction solution was added dropwise to 120 g of hexane to obtain a precipitate. The precipitate was collected by suction filtration and washed several times with 50 g of hexane. Thereafter, the washed product was dried in a vacuum dryer at 60° C. for 12 hours to obtain a homopolymer of glycidyl methacrylate (Mw=2870). In 20.0 g of methyl isobutyl ketone, 5.0 g of the obtained polymer was dissolved. Added were 11.3 g of 4-iodobenzoic acid and 2.6 g of 25% tetramethylammonium hydroxide, and the reaction was conducted at 80° C. for 6 hours. After completion of the reaction, 100.0 g of methyl isobutyl ketone and 100.0 g of a 5% aqueous oxalic acid solution were added and the organic phase was separated. The organic phase was washed with water several times, and then the obtained organic phase was concentrated using an evaporator and added dropwise to 100 g of hexane to obtain a precipitate. The precipitate was collected by suction filtration and washed several times with 50.0 g of hexane. Thereafter, the washed product was dried in a vacuum dryer at 60° C. for 12 hours to obtain a polymer (X-1) represented by formula (X-1). The Mw of the polymer (X-1) was 4420.

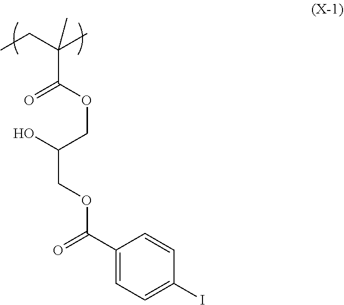

### <Preparation of Composition>

The compounds [A], the solvents [B], the acid generators [C], the crosslinking agents [D], and other components [E] used for the preparation of compositions are shown below.

### [Compound [A]]

### Examples: The Polymers (A-1) to (A-24) and Compounds (A-25) to (A-28)

### Comparative Examples: The Polymer (X-1)

### [Solvent [B]]

B-1: Propylene glycol monomethyl ether acetate

### [Acid Generator [C]]

C-1: Compound represented by formula (C-1)

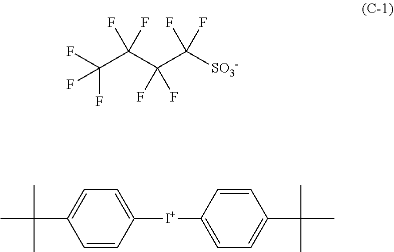

### [Crosslinking Agent [D]]

D-1: A compound represented by formula (D-1)

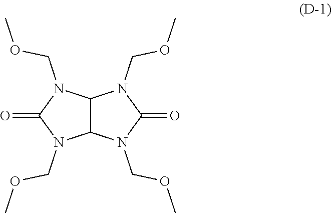

D-2: A compound represented by formula (D-2)

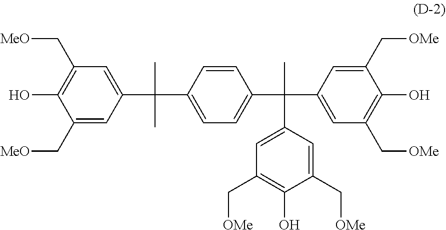 [SMILES: COCc1cc(C(C)(C)c2ccc(C(C)(c3cc(COC)c(O)c(COC)c3)c3cc(COC)c(O)c(COC)c3)cc2)cc(COC)c1O]

### [Other Components [E]]

E-1: A polymer (Mw: 1500) having a repeating unit represented by formula (E-1)
E-2: A polymer (Mw: 1800) having a repeating unit represented by formula (E-2)
E-3: Compound represented by formula (E-3)

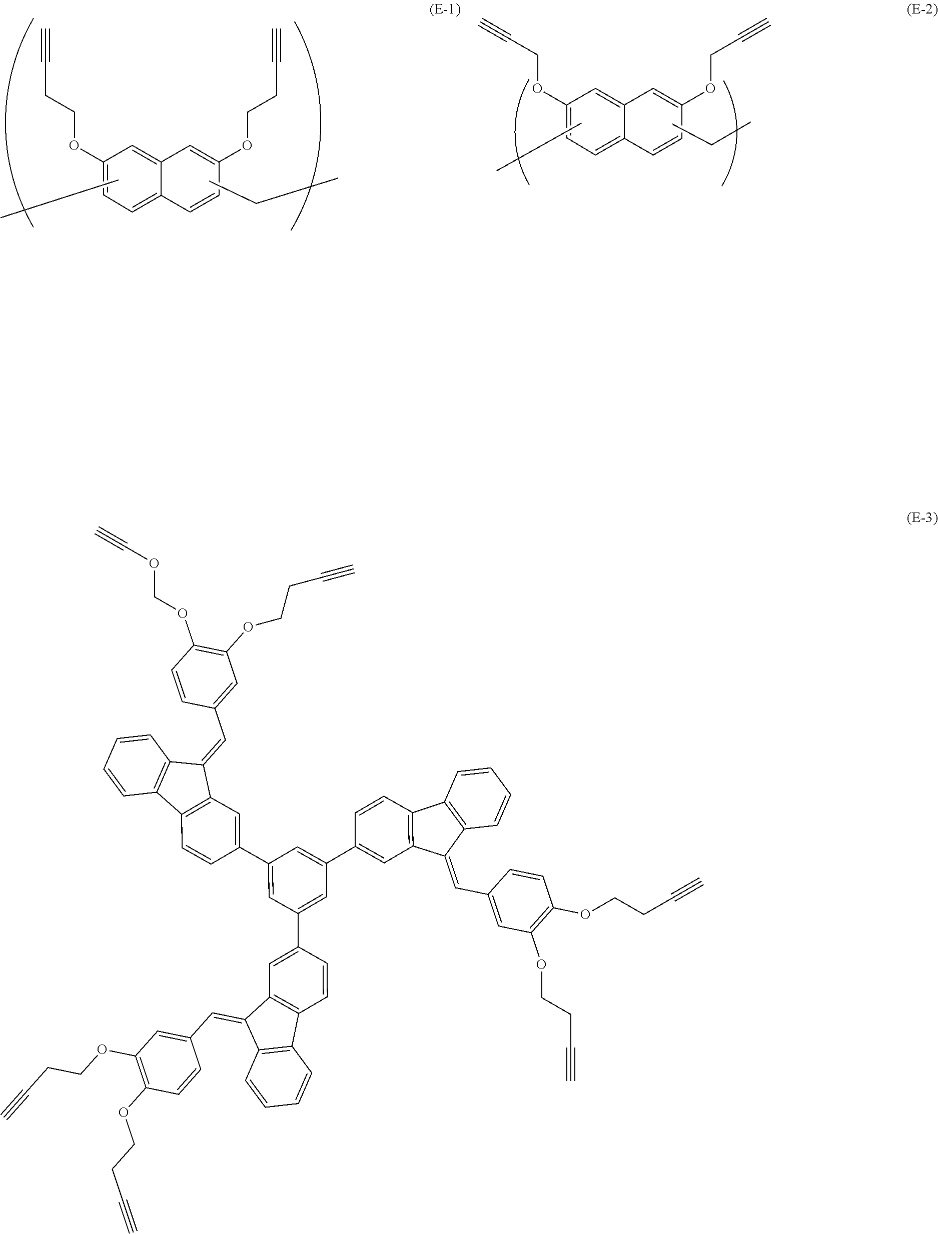

### Example 1-1

In 97.9 parts by mass of (B-1) as a solvent [B], 2 parts by mass of (A-1) as a compound [A], 0.05 parts by mass of (C-1) as an acid generator [C], and 0.05 parts by mass of (D-1) as a crosslinking agent [D] were dissolved. The resulting solution was filtered through a polytetrafluoroethylene (PTFE) membrane filter having a pore size of 0.45 μm to prepare composition (J-1)

### Examples 1-2 to 1-30 and Comparative Example 1-1

Compositions (J-2) to (J-30) and (CJ-1) were prepared in the same manner as in Example 1 except that the components of the types and contents shown in the following Table 1 were used. In Table 1, “-” in the columns of “acid generator [C]” and “crosslinking agent [D]” indicates that the corresponding component was not used.

TABLE 1

| | | | | | | Acid | | Crosslinking | | Other | |
|---|---|---|---|---|---|---|---|---|---|---|---|
| | | Compound [A] | | Solvent [B] | | generator [C] | | agent [D] | | components [E] | |
| | | | Content | | Content | | Content | | Content | | Content |
| | | | (parts | | (parts | | (parts | | (parts | | (parts |
| | Composition | Type | by mass) | Type | by mass) | Type | by mass) | Type | by mass) | Type | by mass) |
| Example 1-1 | J-1 | A-1 | 1.5 | B-1 | 98 | C-1 | 0.05 | D-1 | 0.05 | E-1 | 0.5 |
| Example 1-2 | J-2 | A-1 | 1.5 | B-1 | 98 | C-1 | 0.05 | D-2 | 0.05 | E-2 | 0.5 |
| Example 1-3 | J-3 | A-1 | 1.5 | B-1 | 98 | — | — | D-2 | 0.05 | E-3 | 0.5 |
| Example 1-4 | J-4 | A-2 | 2 | B-1 | 97.9 | C-1 | 0.05 | D-2 | 0.05 | — | — |
| Example 1-5 | J-5 | A-3 | 2 | B-1 | 97.9 | C-1 | 0.05 | D-2 | 0.05 | — | — |
| Example 1-6 | J-6 | A-4 | 2 | B-1 | 97.9 | C-1 | 0.05 | D-2 | 0.05 | — | — |
| Example 1-7 | J-7 | A-5 | 2 | B-1 | 97.9 | C-1 | 0.05 | D-1 | 0.05 | — | — |
| Example 1-8 | J-8 | A-6 | 2 | B-1 | 97.9 | C-1 | 0.05 | D-2 | 0.05 | — | — |
| Example 1-9 | J-9 | A-7 | 2 | B-1 | 97.9 | C-1 | 0.05 | D-2 | 0.05 | — | — |
| Example 1-10 | J-10 | A-8 | 2 | B-1 | 97.9 | C-1 | 0.05 | D-1 | 0.05 | — | — |
| Example 1-11 | J-11 | A-9 | 2 | B-1 | 97.9 | C-1 | 0.05 | D-2 | 0.05 | — | — |
| Example 1-12 | J-12 | A-10 | 2 | B-1 | 97.9 | C-1 | 0.05 | D-2 | 0.05 | — | — |
| Example 1-13 | J-13 | A-11 | 2 | B-1 | 98 | — | — | — | — | — | — |
| Example 1-14 | J-14 | A-12 | 2 | B-1 | 98 | — | — | — | — | — | — |
| Example 1-15 | J-15 | A-13 | 2 | B-1 | 98 | — | — | — | — | — | — |
| Example 1-16 | J-16 | A-14 | 2 | B-1 | 98 | — | — | — | — | — | — |
| Example 1-17 | J-17 | A-15 | 2 | B-1 | 98 | — | — | — | — | — | — |
| Example 1-18 | J-18 | A-16 | 2 | B-1 | 98 | — | — | — | — | — | — |
| Example 1-19 | J-19 | A-17 | 2 | B-1 | 98 | — | — | — | — | — | — |
| Example 1-20 | J-20 | A-18 | 2 | B-1 | 98 | — | — | — | — | — | — |
| Example 1-21 | J-21 | A-19 | 2 | B-1 | 98 | — | — | — | — | — | — |
| Example 1-22 | J-22 | A-20 | 2 | B-1 | 98 | — | — | — | — | — | — |
| Example 1-23 | J-23 | A-21 | 2 | B-1 | 98 | — | — | — | — | — | — |
| Example 1-24 | J-24 | A-22 | 2 | B-1 | 98 | — | — | — | — | — | — |
| Example 1-25 | J-25 | A-23 | 2 | B-1 | 98 | — | — | — | — | — | — |
| Example 1-26 | J-26 | A-24 | 2 | B-1 | 98 | — | — | — | — | — | — |
| Example 1-27 | J-27 | A-25 | 2 | B-1 | 98 | — | — | — | — | — | — |
| Example 1-28 | J-28 | A-26 | 2 | B-1 | 98 | — | — | — | — | — | — |
| Example 1-29 | J-29 | A-27 | 2 | B-1 | 98 | — | — | — | — | — | — |
| Example 1-30 | J-30 | A-28 | 2 | B-1 | 98 | — | — | — | — | — | — |
| Comparative | CJ-1 | X-1 | 2 | B-1 | 98 | C-1 | 0.05 | D-1 | 0.05 | — | — |
| Example 1-1 | | | | | | | | | | | |

### <Evaluation>

Using the compositions for forming a resist underlayer film prepared as described above, the rectangularity of a resist pattern was evaluated by the following method. The evaluation results are given in the following Table 2.

### <Preparation of Resist Composition (R-1)>

A resist composition (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content ratio of each structural unit: (1)/(2)/(3)=65/5/30 (mol %)), 1.0 parts by mass of triphenylsulfonium trifluoromethanesulfonate as a radiation-sensitive acid generator, and 4,400 parts by mass of ethyl lactate and 1,900 parts by mass of propylene glycol monomethyl ether acetate each as a solvent, and filtering the obtained solution through a polytetrafluoroethylene (PTFE) membrane filter having a pore size of 0.2 μm.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. To the silicon-containing film formed as described above was applied the composition for forming a resist underlayer film prepared above, heated at 250° C. for 60 sec, and then cooled at 23° C. for 30 sec. Thus, a resist underlayer film having an average thickness of 5 nm was formed. The resist underlayer film formed was coated with the resist composition (R-1), heated at 130° C. for 60 seconds, and then cooled at 23° C. for 30 seconds. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby obtaining a substrate for evaluation having a resist pattern formed thereon. A scanning electron microscope (“SU8220” available from Hitachi High-Tech Corporation) was used for length measurement and observation of the resist pattern of the substrate for evaluation. The resist pattern rectangularity was evaluated as “A” (good) when the cross-sectional shape of the pattern was rectangular, and “B” (poor) when trailing was present in the cross section of the pattern.

TABLE 2

| | | Resist pattern |
|---|---|---|
| | Composition | rectangularity |
| Example 2-1 | J-1 | A |
| Example 2-2 | J-2 | A |
| Example 2-3 | J-3 | A |
| Example 2-4 | J-4 | A |
| Example 2-5 | J-5 | A |
| Example 2-6 | J-6 | A |
| Example 2-7 | J-7 | A |
| Example 2-8 | J-8 | A |
| Example 2-9 | J-9 | A |
| Example 2-10 | J-10 | A |
| Example 2-11 | J-11 | A |
| Example 2-12 | J-12 | A |
| Example 2-13 | J-13 | A |
| Example 2-14 | J-14 | A |
| Example 2-15 | J-15 | A |
| Example 2-16 | J-16 | A |
| Example 2-17 | J-17 | A |
| Example 2-18 | J-18 | A |
| Example 2-19 | J-19 | A |
| Example 2-20 | J-20 | A |
| Example 2-21 | J-21 | A |
| Example 2-22 | J-22 | A |
| Example 2-23 | J-23 | A |
| Example 2-24 | J-24 | A |
| Example 2-25 | J-25 | A |
| Example 2-26 | J-26 | A |
| Example 2-27 | J-27 | A |
| Example 2-28 | J-28 | A |
| Example 2-29 | J-29 | A |
| Example 2-30 | J-30 | A |
| Comparative | CJ-1 | B |
| Example 2-1 | | |

### <Evaluation>

Using the compositions for forming a resist underlayer film prepared as described above, the rectangularity of the resist pattern and the suppressibility of defects after etching were evaluated by the following methods. The evaluation results are shown in the following Table 3.

### <Preparation of Resist Composition (R-2)>

### [Synthesis of Compound]

The compound (S-1) to be used for the preparation of a resist composition (R-2) was synthesized by the following procedure. Into a reaction vessel, 6.5 parts by mass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)}(OH)ₓ (0<x<3) as a structural unit).

Mixed were 2 parts by mass of the compound (S-1) synthesized above and 98 parts by mass of propylene glycol monoethyl ether, and the obtained mixture was subjected to removal of residual water with activated 4 Å molecular sieve, and then filtered through a polytetrafluoroethylene (PTFE) membrane filter having a pore size of 0.2 μm. Thus, a resist composition (R-2) was prepared.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 seconds, and then cooled at 23° C. for 30 seconds. Thus, a resist underlayer film having an average thickness of 5 nm was formed. The resist underlayer film was coated with the resist composition (R-2) by the spin coating method using a spin coater described above, and after a lapse of a prescribed time, heated at 90° C. for 60 seconds, and then cooled at 23° C. for 30 seconds. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 seconds, and subsequently cooled at 23° C. for 60 seconds. Thereafter, development was performed by a paddle method using 2-heptanone (20 to 25° C.), and then dried to obtain a substrate for evaluation with a resist pattern formed thereon. A scanning electron microscope (“SU8220” available from Hitachi High-Tech Corporation) was used for length measurement and observation of the resist pattern of the substrate for evaluation. The resist pattern rectangularity was evaluated as “A” (good) when the cross-sectional shape of the pattern was rectangular, and “B” (poor) when trailing was present in the cross section of the pattern.

[Suppressibility of Defect after Etching]

The substrate for evaluation on which a resist pattern was formed using the resist composition (R-2) was treated under the conditions of O₂=400 sccm, PRESS.=25 MT, HF RF=400 W, LF RF=0 W, DCS=0 V, and RDC=50% using an etching apparatus (“TACTRAS” available from Tokyo Electron Limited), and the resist underlayer film was selectively removed using the resist pattern as a mask to obtain a substrate for evaluation. A scanning electron microscope (“SU8220” available from Hitachi High-Tech Corporation) was used for observation of the pattern of the substrate for evaluation. The suppressibility of defects after etching was evaluated as “A” (good) when there was no residue (defect) at the portion where the resist underlayer film had been selectively removed in the cross section of the resist underlayer film pattern, and as “B” (poor) when there were residues (defects).

TABLE 3

| | | Resist | Suppressibility |
|---|---|---|---|
| | | pattern | of defect |
| | Composition | rectangularity | after etching |
| Example 3-1 | J-1 | A | A |
| Example 3-2 | J-2 | A | A |
| Example 3-3 | J-3 | A | A |
| Example 3-4 | J-4 | A | A |
| Example 3-5 | J-5 | A | A |
| Example 3-6 | J-6 | A | A |
| Example 3-7 | J-7 | A | A |
| Example 3-8 | J-8 | A | A |
| Example 3-9 | J-9 | A | A |
| Example 3-10 | J-10 | A | A |
| Example 3-11 | J-11 | A | A |
| Example 3-12 | J-12 | A | A |
| Example 3-13 | J-13 | A | A |
| Example 3-14 | J-14 | A | A |
| Example 3-15 | J-15 | A | A |
| Example 3-16 | J-16 | A | A |
| Example 3-17 | J-17 | A | A |
| Example 3-18 | J-18 | A | A |
| Example 3-19 | J-19 | A | A |
| Example 3-20 | J-20 | A | A |
| Example 3-21 | J-21 | A | A |
| Example 3-22 | J-22 | A | A |
| Example 3-23 | J-23 | A | A |
| Example 3-24 | J-24 | A | A |
| Example 3-25 | J-25 | A | A |
| Example 3-26 | J-26 | A | A |
| Example 3-27 | J-27 | A | A |
| Example 3-28 | J-28 | A | A |
| Example 3-29 | J-29 | A | A |
| Example 3-30 | J-30 | A | A |
| Comparative | CJ-1 | B | B |
| Example 3-1 | | | |

As can be seen from the results in Tables 2 and 3, the resist underlayer films formed from the compositions for forming a resist underlayer film of Examples were superior in resist pattern rectangularity and suppressibility of defects after etching to the resist underlayer films formed from the compositions for forming a resist underlayer film of Comparative Examples.

According to the composition for forming a resist underlayer film of the present disclosure, it is possible to form a film excellent in resist pattern rectangularity. According to the method for manufacturing a semiconductor substrate of the present disclosure, it is possible to efficiently manufacture a semiconductor substrate since a composition for forming a resist underlayer film capable of forming a resist underlayer film excellent in resist pattern rectangularity is used. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A composition comprising:
a compound comprising an iodine atom; and
a solvent, wherein
the compound comprising an iodine atom is a polymer comprising a repeating unit represented by formula (1), an aromatic ring-containing compound comprising an iodine atom and having a molecular weight of 750 or more and 3,000 or less, or a combination thereof, and
a content ratio of the compound comprising an iodine atom to components other than the solvent in the composition for forming an underlayer film is 50% by mass or more: 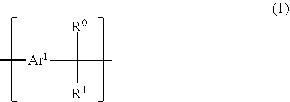
in the formula (1), Ar¹ is a divalent group comprising an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ comprises an iodine atom.

2. The composition according to claim 1, wherein R¹ is a group comprising an aromatic ring having 5 to 40 ring members.

3. The composition according to claim 2, wherein at least one hydrogen atom of the aromatic ring is substituted with an iodine atom.

4. The composition according to claim 1, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

5. The composition according to claim 1, wherein the compound comprising an iodine atom comprises at least one group selected from the group consisting of a hydroxy group, a group represented by the formula (2-1), and a group represented by formula (2-2): 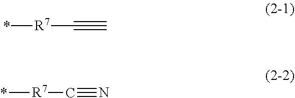
in the formulas (2-1) and (2-2), each R⁷ is independently a divalent organic group having 1 to 20 carbon atoms or a single bond; and * is a bond with a carbon atom in an aromatic ring.

6. The composition for forming a resist underlayer film according to claim 1, which is suitable for forming an underlayer film of a resist film to be exposed to extreme ultraviolet rays.

7. The composition for forming a resist underlayer film according to claim 6, which is suitable for forming an underlayer film of a metal-containing resist film.

8. A method for manufacturing a semiconductor substrate, the method comprising:
applying a composition for forming a resist underlayer film directly or indirectly to a substrate to form a resist underlayer film;
applying a composition for forming a resist film to the resist underlayer film to form a resist film;
exposing the resist film to extreme ultraviolet rays; and
developing at least the exposed resist film,
wherein the composition for forming a resist underlayer film comprises:
a compound comprising an iodine atom; and
a solvent, wherein
the compound comprising an iodine atom is a polymer comprising a repeating unit represented by formula (1), an aromatic ring-containing compound comprising an iodine atom and having a molecular weight of 750 or more and 3,000 or less, or a combination thereof, and
a content ratio of the compound comprising an iodine atom in components other than the solvent in the composition for forming an underlayer film is 50% by mass or more: 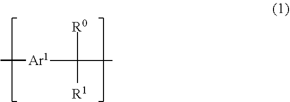
in the formula (1), Ar¹ is a divalent group comprising an aromatic ring having 5 to 40 ring atoms; and R⁰ is a hydrogen atom or a monovalent organic group having 1 to 40 carbon atoms, R¹ is a monovalent organic group having 1 to 40 carbon atoms, and at least one of Ar¹, R⁰ or R¹ comprises an iodine atom.

9. The method for manufacturing a semiconductor substrate according to claim 8, wherein R¹ is a group comprising an aromatic ring having 5 to 40 ring members.

10. The method for manufacturing a semiconductor substrate according to claim 9, wherein at least one hydrogen atom of the aromatic ring is substituted with an iodine atom.

11. The method for manufacturing a semiconductor substrate according to claim 8, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

12. The method for manufacturing a semiconductor substrate according to claim 8, wherein the compound comprising an iodine atom has at least one group selected from the group consisting of a hydroxy group, a group represented by formula (2-1), and a group represented by formula (2-2): 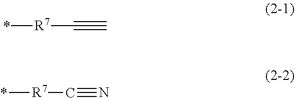
in the formulas (2-1) and (2-2), each R⁷ is independently a divalent organic group having 1 to 20 carbon atoms or a single bond; and * is a bond with a carbon atom in an aromatic ring.

13. The method for manufacturing a semiconductor substrate according to claim 8, wherein the resist film comprises a metal.
